(19) United States
(12) Patent Application Publication
(10) Pub. No.: US 2009/0009169 A1
(43) Pub. Date: Jan. 8, 2009

(54) Low Local Sar Birdcage Radio Frequency Coil

(75) Inventor: Volkmar Schulz, Hamburg (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 11/570,509

(22) PCT Filed: Jun. 2, 2005
(86) PCT No.: PCT/IB05/51808

§ 371 Date: Sep. 19, 2008

Related U.S. Application Data
(60) Provisional application No. 60/581,112, filed on Jun. 18, 2004.

(51) Int. Cl. G01R 33/34; H01F 7/06

(52) U.S. Cl. 324/318; 29/602.1

(57) ABSTRACT

A radio frequency coil (30) for detecting magnetic resonance signals includes a plurality of distributed-capacitance rungs (70) and one or more conductive segments or rings (72, 74, 100) arranged transverse to the rungs (70) and coupled with the rungs (70). Each rung (70) includes: (i) an insulating substrate (80) having first and second principal 5 sides (82, 84); (ii) a first plurality of spaced apart conductive regions (86) on the first principal side; and (iii) a second plurality of spaced apart conductive regions (88) on the second principal side. The first and second pluralities of spaced apart conductive regions (86, 88) are staggered to efficiently capacitively couple at the magnetic resonance frequency to define a distributed capacitance.

The following relates to the magnetic resonance arts. It finds particular application in magnetic resonance imaging at high magnetic field, and will be described with particular reference thereto. However, it also finds application in magnetic resonance imaging generally, as well as in magnetic resonance spectroscopy and related magnetic resonance techniques.

In designing magnetic resonance imaging scanners, tradeoffs are involved between space allocated to the main magnetic field coils, the magnetic field gradient coils, and the radio frequency coil. One approach for reducing the volume or thickness displaced by the whole-body radio frequency birdcage coil is to employ planar foil rungs and end rings. However, the current in each rung is increased in thin foil rungs, resistive losses are increased, and the specific absorption ratio (SAR) is adversely impacted. These problems become more acute at higher magnetic fields.

Moreover, at higher magnetic fields, the magnetic resonance frequency increases and the corresponding wavelength decreases, increasing the adverse impact of discrete capacitors on the local SAR. Discrete capacitors also can generate substantial radio frequency field non-uniformities at higher operating frequencies. Adding additional discrete capacitors to distribute and reduce these effects increases manufacturing complexity and enlarges the total volume of the radio frequency coil.

The present invention contemplates improved apparatuses and methods that overcomes the aforementioned limitations and others.

According to one aspect, a radio frequency coil is disclosed for detecting magnetic resonance signals. A plurality of distributed-capacitance rungs each include: (i) an insulating substrate having first and second principal sides; (ii) a first plurality of spaced apart conductive regions on the first principal side; and (iii) a second plurality of spaced apart conductive regions on the second principal side. The first and second pluralities of spaced apart conductive regions are coupled at the magnetic resonance frequency to define a distributed capacitance. One or more conductive segments are arranged transverse to the rungs and coupled with the rungs.

According to another aspect, a magnetic resonance imaging scanner comprises a main magnet generating a substantially spatially and temporally constant magnetic field in an examination region, magnetic field gradient coils generating selected magnetic field gradients in the examination region, and a radio frequency coil. The radio frequency coil includes a plurality of distributed-capacitance rungs and one or more conductive segments arranged transverse to the rungs and coupled with the rungs. Each rung includes: (i) an insulating substrate having first and second principal sides; (ii) a first plurality of spaced apart conductive regions on the first principal side; and (iii) a second plurality of spaced apart conductive regions on the second principal side. The first and second pluralities of spaced apart conductive regions are coupled at the magnetic resonance frequency to define a distributed capacitance.

According to yet another aspect, a method for manufacturing a radio frequency coil is provided. A first plurality of spaced apart conductive regions are formed on a first principal side of an insulated rung substrate. A second plurality of spaced apart conductive regions are formed on a second principal side of the insulated rung substrate opposite the first principal side. The forming of the first and second pluralities of spaced apart conductive regions are repeated for a plurality of insulated rung substrates to form a plurality of distributed capacitance rungs. The rungs are connected with one or more transverse conductive segments.

One advantage resides in providing a reduced radio frequency coil thickness without increasing current dissipation.

Another advantage resides in providing a radio frequency coil with reduced current dissipation without increasing the coil thickness.

Another advantage resides in simplifying fabrication and in facilitating the fabrication of complex coil designs.

Yet another advantage resides in providing a radio frequency coil with reduced the specific absorption ratio (SAR).

Still yet another advantage resides in improved radio frequency field homogeneity and improved signal to noise ratio (SNR).

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

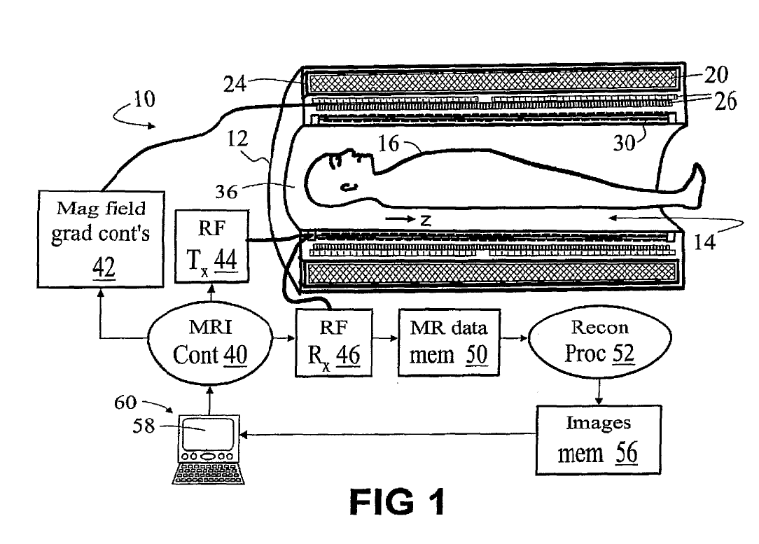

FIG. 1 diagrammatically shows a magnetic resonance imaging system including a radio frequency coil with rungs having distributed capacitance.

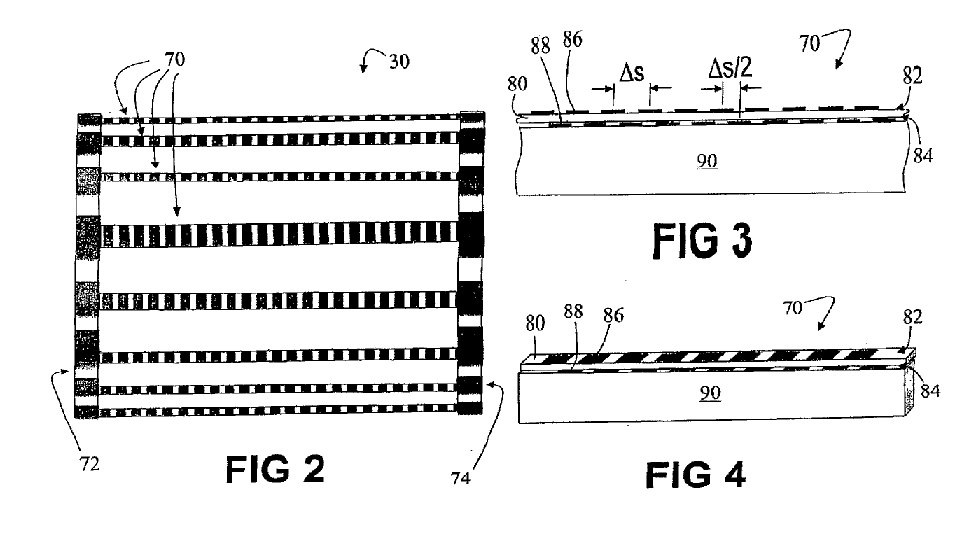

FIG. 2 diagrammatically shows a side view of a radio frequency coil.

FIG. 3 diagrammatically shows a side view of a portion of one of the rungs of the radio frequency coil of FIG. 2.

FIG. 4 diagrammatically shows a perspective view of a portion of one of the rungs of the radio frequency coil of FIG. 2.

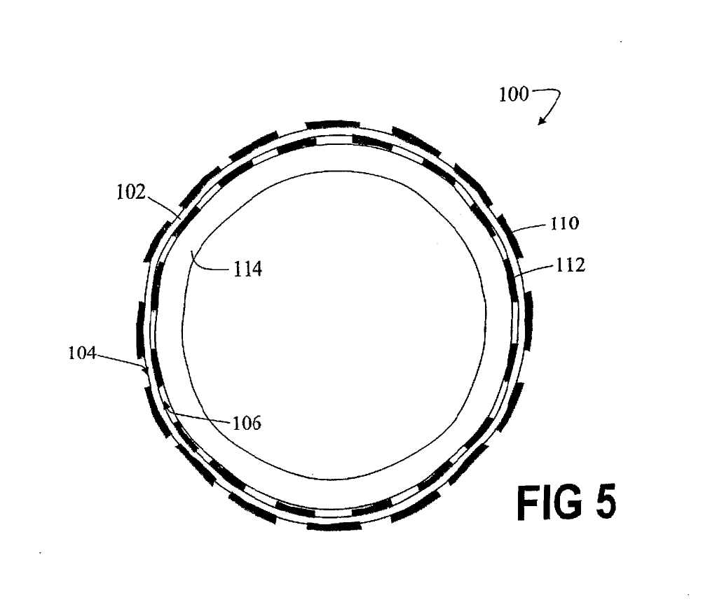

FIG. 5 diagrammatically shows an end view of one of the rings of the radio frequency coil of FIG. 2.

With reference to FIG. 1, a magnetic resonance imaging scanner 10 includes a housing 12 defining a generally cylindrical scanner bore 14 inside of which an associated imaging subject 16 is disposed. Main magnetic field coils 20 are disposed inside the housing 12, and produce a substantially spatially and temporally constant B₀ magnetic field, directed generally along a z-direction in FIG. 1, within an imaging region contained in the scanner bore 14. B₀ fields on the order of 3 T to 7 T are preferred, but fields higher than 7 T and as low as a fraction of a Tesla are also contemplated. Typically, the main magnetic field coils are superconducting coils disposed inside of cryoshrouding 24. However, resistive main magnetic field coils can also be employed.

The housing 12 also houses or supports magnetic field gradient-generating structures, such as magnetic field gradient coils 26, for selectively producing magnetic field gradients parallel to the z-direction, transverse to the z-direction, or along other selected directions. The housing 12 further houses or supports a radio frequency body coil 30, having rungs with highly distributed capacitances, for selectively exciting magnetic resonances. Specifically, the radio frequency body coil 30 produces a radio frequency B₁ magnetic field transverse to the main B₀ magnetic field. The radio frequency B₁ magnetic field is generated at the Larmor frequency for exciting a nuclear magnetic resonance. For proton imaging at 7 T, a B₁ frequency of about 298 MHz is suitable, while at 3 T a B₁ frequency of about 128 MHz is suitable. In the illustrated embodiment, the coil 30 is a whole body birdcage coil; however, the distributed capacitance conductors described herein can also be used in a head coil, with or without an end cap, or in other types of local coils. The housing 12 typically includes a cosmetic inner liner 36 disposed inside the birdcage coil 30 defining the scanner bore 14.

During imaging, the main magnetic field coils 20 produce the spatially and temporally constant B₀ magnetic field parallel to the z-direction in the bore 14 within the imaging region. A magnetic resonance imaging controller 40 operates magnetic field gradient controllers 42 to selectively energize the magnetic field gradient coils 26, and operates a radio frequency transmitter 44 coupled to the radio frequency coil 30 to selectively energize the radio frequency coil 30. By selectively operating the magnetic field gradient coils 26 and the radio frequency coil 30, magnetic resonance is generated and spatially encoded in at least a portion of the region of interest of the imaging subject 16. By applying selected magnetic field gradients via the gradient coils 26, a selected k-space trajectory is traversed during acquisition of magnetic resonance signals, such as a Cartesian trajectory, a plurality of radial trajectories, or a spiral trajectory. A radio frequency receiver 46, also coupled with the radio frequency coil 30, receives magnetic resonance samples during traversal of the k-space trajectory. The samples are stored in a magnetic resonance data memory 50. Alternatively, separate transmit and receive radio frequency coils are used, one or both of which can employ distributed capacitance conductors such as are described herein.

The magnetic resonance data are reconstructed by a reconstruction processor 52 into one or more reconstructed images. In the case of k-space sampling data, a Fourier transform-based reconstruction algorithm can be employed. Other reconstruction algorithms, such as a filtered backprojection-based reconstruction, may also be used depending upon the format of the acquired magnetic resonance imaging data. The reconstructed image or images generated by the reconstruction processor 52 are stored in an images memory 56, and can be displayed on a display 58 of a user interface 60, stored in non-volatile memory, transmitted over a local intranet or the Internet, viewed, stored, manipulated, or so forth. The user interface 60 can also enable a radiologist, technician, or other operator of the magnetic resonance imaging scanner 10 to communicate with the magnetic resonance imaging controller 40 to select, modify, and execute magnetic resonance imaging sequences.

The described magnetic resonance imaging system is an example. The radio frequency coils described herein can be employed with substantially any type of magnetic resonance imaging scanner, such as an open magnet scanner, a vertical magnet scanner, or so forth. Moreover, the radio frequency coils described herein can be employed in magnetic resonance procedures other than imaging, such as in magnetic resonance spectroscopy.

With reference to FIG. 2, the radio frequency coil 30 includes a plurality of rungs 70 arranged generally parallel to one another in the illustrated embodiment, and one or more conductive segments or rings arranged transverse to the rungs 70. In the illustrated embodiment of FIG. 2, there are two rings 72, 74 in the vicinity of opposite ends of the rungs 70. In the illustrated coil 30, the two rings 72, 74 are coupled with the rungs 70 at the magnetic resonance frequency to define a birdcage coil. Optionally, a conductive end cap (not shown) or other associated structure may also be included. For example, some head coils include a conductive end plate. Moreover, a radio frequency shield or screen typically surrounds the coil 30, but is not illustrated herein.

With continuing reference to FIG. 2 and with further reference to FIGS. 3 and 4, each rung 70 includes an insulating rung substrate 80 having first and second principal sides 82, 84. A first plurality of spaced apart conductive regions 86 are disposed on the first principal side 82. A second plurality of spaced apart conductive regions 88 are disposed on the second principal side 84. The first and second principal sides 82, 84 are separated by a thickness of the insulating rung substrate 80 chosen to provide a selected distributed capacitive coupling between the first and second pluralities of conductive regions 86, 88. Thus, the rung substrate 80 along with the first and second pluralities of conductive regions 86, 88 collectively define a distributed capacitance having a selected capacitance per unit length along the rung 70. In the illustrated embodiment, a spacing As between the conductive regions is the same for both the first plurality of spaced apart conductive regions 86 and the second plurality of spaced apart conductive regions 88; however, the second plurality of spaced apart conductive regions 88 are staggered respective to the first plurality of spaced apart conductive regions 86 by a staggering distance Δs/2 to improve the capacitive coupling. Staggering ratios of other than one-half of the spacing are also contemplated. Preferably, the first and second conductive regions 86, 88 are platelets of common size. However, a non-uniform sized distribution of the platelets along the rung can also be employed, for example to adjust the distributed capacitance to correct for radio frequency field non-uniformities.

Typically, the first and second principal sides 82, 84 are separated by a thickness of the insulating rung substrate 80 chosen to be between three microns and thirty microns, which typically provides distributed capacitive coupling suitable for magnetic resonance imaging applications. The distributed capacitance per unit length depends upon factors such as the thickness of the rung substrate 80, the dielectric constant of the material comprising the rung substrate 80, the spacing Δs of the conductive regions, the staggering of the second plurality of spaced apart conductive regions 88 respective to the first plurality of spaced apart conductive regions 86, and the size and dimensions of the conductive regions. Those skilled in the art can readily compute values for these parameters which provide a specific distributed capacitance per unit length using conventional electromagnetic formulas or commercial electromagnetic simulation software. In some embodiments, at least twenty conductive regions are included in each of the first and second pluralities of conductive regions 86, 88 to provide a substantially spatially uniform distributed capacitance. For a fixed rung length, increasing the number of conductive regions generally improves radio frequency field uniformity and reduces the maximum local SAR. Preferably, the conductive regions are less than one centimeter in length such that a rung a meter long defines hundreds of capacitors.

One suitable process for fabricating the rungs 70 starts with a double-sided printed circuit board having a copper film or other conductive coating disposed on both principal sides. The insulating board portion of the printed circuit board is chosen to have the desired thickness of the rung substrate 80. The printed circuit board is cut or trimmed to match the desired length and width dimensions. Lithographically controlled chemical etching, laser cutting, or another metal removal process is used to remove portions of the copper film on each side such that the remaining portions of the copper film define the first and second pluralities of spaced apart conductive regions 86, 88. Alternatively, a lithographically controlled lift-off process can be employed to selectively deposit the copper only in regions corresponding to the conductive regions of the rung 70. These process operations are standard printed circuit board fabrication process operations.

Because the rung substrate 80 is generally thin, such as between three microns and thirty microns in some preferred embodiments, it is generally insufficiently rigid for stand-alone use in the magnetic resonance scanner 10. Accordingly, after the first and second pluralities of spaced apart conductive regions 86, 88 are formed, one or both principal sides are bonded to rigid insulating mechanical support substrates that are generally thicker than the rung substrate 80. In the specific embodiment illustrated in FIGS. 3 and 4, the second principal side 84 is bonded to a mechanical support substrate 90, while the first principal side 82 is not bonded to a support substrate. Optionally, however, both principal sides can be bonded to mechanical support substrates to provide further rigidity and to protect the conductive regions from abrasion or other damage. In other embodiments, mechanical support is provided by bonding the rung substrate 80 onto another component of the magnetic resonance imaging scanner 10. For example, the etched rung substrates 80 can be bonded to a former or other structural support that supports the gradient coils 26, or can be bonded onto the backside of the cosmetic liner 36, or so forth.

In some manufacturing embodiments, the lithographic, laser cutting, or other processing defining the first and second pluralities of spaced apart conductive regions 86, 88 is performed on a large printed circuit board substrate having a width spanning several rung widths. After the lithographic processing, the large printed circuit board is cut into individual rungs. Alternatively, rather than separating the individual rungs by cutting, the large printed circuit board can be bent to curve the large printed circuit board to fit a former defining the coil shape. In these embodiments, the rungs 70 are disposed in the scanner 10 on a common rung substrate that supports all the rungs 70 of the coil 30. In birdcage embodiments employing a common substrate, the common substrate is bent or otherwise shaped into a generally cylindrical shape with the rungs 70 parallel to a cylinder axis of the cylinder shape.

In some embodiments, it is contemplated to etch or laser cut one side of the double-coated printed circuit board to define the first plurality of conductive regions 86, then to bond the first principal side 82 to the rigid mechanical support substrate, followed by etching or cutting of the gaps on the opposite principal side to define the second plurality of conductive regions 88.

It should be appreciated that each rung may include dozens, hundreds, or more spaced apart conductive regions. Fabricating such small features is straightforward using conventional lithography-based printed circuit board fabrication techniques. Moreover, because the manufacturing is amenable to mass processing, a large number of rungs can be included in each radio frequency coil. For example, it is contemplated to include several hundred rungs in a single birdcage coil. Using a large number of rungs improves radio frequency field uniformity and reduces the maximum local SAR. The fabricated rungs 70 are connected with the one or more conductive rings 72, 74. In some embodiments, the rings include conductors connected by discrete capacitors.

With reference to FIG. 5, in other embodiments the rings 72, 74 are distributed-capacitance rings fabricated in a manner similar to the described fabrication of the distributed-capacitance rungs 70. The example ring 100 illustrated in FIG. 5 can correspond, for example, to the conductive rings 72, 74 of FIG. 2. The ring 100 includes a ring substrate 102 which is analogous to the rung substrate 80. The ring substrate 102 includes outer and inner principal sides 104, 106 which are analogous to the first and second principal sides 82, 84 of the rung substrate 80. A first plurality of spaced apart conductive regions 110 are disposed on the outer principal side 104, and a second plurality of spaced apart conductive regions 112 are disposed on the outer principal side 106. These pluralities of spaced apart conductive regions 110, 112 are analogous to the first and second pluralities of spaced apart conductive regions 86, 88 of the rungs 70.

Typically, the ring substrate 102 is thin, for example between about three microns and about thirty microns thick, and flexible. The flexible ring substrate 102 is disposed on or in a ring-shaped rigid former to define the desired shape of the conductive ring 100. In the embodiment illustrated in FIG. 5, after formation of the first and second pluralities of spaced apart conductive regions 110, 112, the inner principal surface 106 is bonded to a ring-shaped rigid insulating former 114. Optionally, a second ring-shaped former is also provided to cover the other principal surface 104. In other contemplated embodiments, a ring-shaped former includes an annular groove for receiving the flexible ring substrate 102. In still yet other embodiments, the flexible ring substrate 102 is bonded to another component of the magnetic resonance imaging scanner 10, such as to a surface of a former supporting the gradient coils 26, to a backside surface of the cosmetic liner 36, or so forth.

In the embodiment illustrated in FIG. 5, conductive regions are disposed on both the inner and outer principal sides 104, 106 of the ring substrate 102. In other embodiments, conductive regions may be disposed on only one of the inner and outer sides. That is, one of the first and second pluralities of conductive regions 110, 112 of the ring 100 is optionally omitted.

With returning reference to FIG. 2, the connection of the rungs 70 and the one or more rings 72, 74 can be accomplished by various processes, such as brazing, welding, soldering, or the like, to mechanically and electrically couple the rungs 70 with the rings 72, 74. It is also contemplated to employ capacitive electrical coupling between the rings and rungs without physically connecting conductive regions of the rings and the rungs. The capacitive couplings can be achieved by lapped conductive regions as described above.

Although described with respect to circular, oval, or round birdcage coils, the present technique is also applicable to semi-round, flat, or otherwise-shaped coils. All of the conductors can be formed by metal removal or deposition on opposite sides of a common substrate. a coil which is manufactured flat can be fitted to a structural substrate or former with other contours. Alternatively, strips of the construction described above with reference to the rungs 80 can be applied like tape to a structural substrate of a selected contour.

After the coil is formed, conductive material is optionally added or removed to tune the coil more precisely to the selected frequency. Alternatively or additionally, varactor diodes, preamplifiers, or other electronic components can be used to electronically tune the coil, or can be used to detune the coil when it is not in use.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A radio frequency coil for detecting magnetic resonance signals, the radio frequency coil comprising:
a plurality of distributed-capacitance rungs, each rung including: (i) an insulating substrate having first and second principal sides, (ii) a first plurality of spaced apart conductive regions on the first principal side, and (iii) a second plurality of spaced apart conductive regions on the second principal side, the first and second pluralities of spaced apart conductive regions being coupled at the magnetic resonance frequency to define a distributed capacitance; and
one or more conductive segments arranged transverse to the rungs and coupled with the rungs.

2. The radio frequency coil as set forth in claim 1, wherein the second plurality of spaced apart conductive regions are staggered respective to the first plurality of spaced apart conductive regions.

3. The radio frequency coil as set forth in claim 1, wherein the one or more conductive segments each include:
a conductive loop.

4. The radio frequency coil as set forth in claim 1, wherein each conductive segment includes:
an insulating substrate loop having outer and inner principal sides;
an plurality of spaced apart conductive regions disposed on at least one of the outer principal side and the inner principal side.

5. The radio frequency coil as set forth in claim 1, wherein each conductive segment further includes:
an insulating substrate loop having outer and inner principal sides;
an outer plurality of spaced apart conductive regions disposed on the outer principal side; and
an inner plurality of spaced apart conductive regions disposed on the inner principal side, the outer and inner pluralities of spaced apart conductive regions being capacitively coupled at the magnetic resonance signal frequency.

6. The radio frequency coil as set forth in claim 1, wherein the insulating substrate of the plurality of distributed-capacitance rungs is a common substrate extending between the rungs and supporting the first and second pluralities of spaced apart conductive regions of the plurality of rungs.

7. The radio frequency coil as set forth in claim 1, wherein the first plurality of spaced apart conductive regions include at least twenty conductive regions, and the second plurality of spaced apart conductive regions include at least twenty conductive regions.

8. The radio frequency coil as set forth in claim 1, wherein the first plurality of spaced apart conductive regions include at least one hundred conductive regions, and the second plurality of spaced apart conductive regions include at least one hundred conductive regions.

9. The radio frequency coil as set forth in claim 1, wherein the conductive regions are each less than one centimeter in length.

10. The radio frequency coil as set forth in claim 1, wherein each rung further includes:
a support structure.

11. The radio frequency coil as set forth in claim 1, wherein the first and second principal surfaces of each insulating substrate are separated by a thickness of between about three microns and about thirty microns.

12. A magnetic resonance imaging scanner comprising:
a main magnet generating a substantially spatially and temporally constant magnetic field in an examination region;
magnetic field gradient coils generating selected magnetic field gradients in the examination region; and
a radio frequency coil as set forth in claim 1.

13. A method for manufacturing a radio frequency coil, the method comprising:
forming a plurality of distributed capacitance rungs by:
forming a first plurality of spaced apart conductive regions on a first principal side of an insulated rung substrate, and
forming a second plurality of spaced apart conductive regions on a second principal side of the insulated rung substrate opposite the first principal side; and
connecting the rungs with one or more transverse conductive segments.

14. The method as set forth in claim 13, further including:
selecting a thickness of the insulated rung substrate to provide a selected capacitive coupling between the first and second pluralities of spaced apart conductive regions.

15. The method as set forth in claim 13, wherein the forming of the first and second pluralities of spaced apart conductive regions include:
on a printed circuit board having conductive films deposited on first and second opposite principal sides, forming gaps in the conductive film disposed on the first principal side to define the first plurality of spaced apart conductive regions; and
forming gaps in the conductive film disposed on the second principal side to define the second plurality of spaced apart conductive regions.

16. The method as set forth in claim 13, further including:
after the forming of first and second pluralities of spaced apart conductive regions, securing at least one of the first and second principal sides to an insulating support that is more rigid than the insulated rung substrate in a selected coil pattern.

17. The method as set forth in claim 13, further including:
forming each transverse conductive segment by forming (i) a first plurality of spaced apart conductive regions on a first principal side of an insulated segment substrate and (ii) a second plurality of spaced apart conductive regions on a second principal side of the insulated segment substrate, the first and second pluralities of spaced apart conductive regions capacitively coupling with each other.

18. The method as set forth in claim 17, wherein the forming of each transverse conductive segment further comprises:
after forming the first plurality of spaced apart conductive regions, disposing the insulated segment substrate on or in a ring-shaped former.

19. The method as set forth in claim 13, wherein the connecting of the rungs with one or more transverse conductive segments includes:
connecting the rungs with one or more rings.

20. The method as set forth in claim 13, wherein the forming of the first and second pluralities of spaced apart conductive regions includes:
forming the first and second pluralities of spaced apart conductive regions of the plurality of distributed capacitance rungs on a common substrate that extends between the rungs.

21. The method as set forth in claim 20, further including:
forming the common substrate into a generally cylindrical shape with the rungs parallel to a cylinder axis of the cylinder shape.
